(19) United States
(12) Patent Application Publication
(10) Pub. No.: US 2023/0056353 A1
(43) Pub. Date: Feb. 23, 2023

(54) MICRO SCANNING MIRROR

(71) Applicant: Coretronic MEMS Corporation, Miaoli County (TW)

(72) Inventors: Shih-Chi Liu, Miaoli County (TW); Wei-Leun Fang, Miaoli County (TW); Kai-Chih Liang, Miaoli County (TW); Kai-Chieh Chang, Miaoli County (TW); Ming-Ching Wu, Miaoli County (TW)

(73) Assignee: Coretronic MEMS Corporation, MIAOLI COUNTY (TW)

(21) Appl. No.: 17/879,800

(22) Filed: Aug. 3, 2022

(30) Foreign Application Priority Data
Aug. 18, 2021 (CN) 202110946870.8

(51) Int. Cl. B81B 7/02

(52) U.S. Cl. CPC B81B 7/02; B81B 2201/042; B81B 2203/0118; B81B 2203/04; B81B 2203/056

(57) ABSTRACT

A micro scanning mirror, including a fixed substrate, a lens, and multiple cantilevers, are provided. Each cantilever includes a piezoelectric material structure, multiple first drive electrodes, and multiple second drive electrodes. The piezoelectric material structure includes a connecting part, a folding part, and a fixed part. The connecting part connects the lens along a direction parallel to a central axis of the lens. The folding part has a bending region and multiple drive electrode regions. The fixed part is connected to the fixed substrate, and the folding part is connected to the connecting part and the fixed part. The first drive electrodes and the second drive electrodes are respectively located in the corresponding drive electrode regions in the folding part. The micro scanning mirror of the disclosure can drive a large-sized micro mirror to rotate at an appropriate rotation angle.

### CROSS-REFERENCE TO RELATED APPLICATION

This application claims the priority benefit of China application serial no. 202110946870.8, filed on Aug. 18, 2021. The entirety of the above-mentioned patent application is hereby incorporated by reference herein and made a part of this specification.

### BACKGROUND

### Technical Field

The disclosure relates to a micro electromechanical systems (MEMS) element, and particularly relates to a micro scanning mirror.

### Description of Related Art

The reflective micro mirror is mainly used in applications such as optical projection, optical communication, optical ranging radar, etc. The micro mirror element designed by the micro electromechanical systems (MEMS) combined with semiconductor process integrated manufacturing technology can implement mass production to save cost, miniaturization, integration with electronic circuits, and other advantages as compared with the micro mirror manufactured by precision processing. The micro mirror is a passive element, so an external driving force is required to drive the micro mirror to rotate. External driving measures may be divided into three main types, which include the electrostatic drive, the electromagnetic drive, and the piezoelectric drive. At present, the micro mirror elements obtained by semiconductor manufacturing on the market are mainly the electrostatic type and the electromagnetic type with main reasons being that the materials are relatively easy to obtain, and the semiconductor process technology and the external assembly technology are mature. However, the downsides include small rotation angle, large driving voltage, electromagnetic heating, insufficient resistance to external impact, etc.

The electrostatic driving measure drives the micro mirror by multiple sets of parallelly interlaced capacitor plates together with the electrostatic force generated by the fringe effect of the electric field on the parallel capacitor plates. When there is an external vibration or impact, if the comb-like structure touches each other, a short circuit occurs immediately, causing the element to fail. Also, the process yield is poor, which causes the competitive advantage in production cost of the element to be lost.

On the other hand, the electromagnetic driving measure is to lay electromagnetic coils on the micro mirror and lay permanent magnets or ferromagnetic materials on the periphery of the micro mirror. When an external alternating current is applied to the coil, the micro mirror is driven by the Lorentz force generated by the magnetic effect of the current. However, the electromagnetic driving measure requires electroplating of coils and assembly of external magnets above the micro mirror, which is not conducive to assembly and the trend of miniaturization of the element.

The piezoelectric driving measure uses the characteristics of piezoelectric materials. When an external voltage is applied to the piezoelectric material, the piezoelectric material generates a strain force, which then drives the structure to be deformed, so as to drive the micro mirror to rotate. The electromechanical conversion efficiency of the piezoelectric material is the highest compared with the two measures above.

However, the diameter of the micro mirror in the current piezoelectric driving measure is mostly 1 mm, which is mainly used in the application of the scanning mirror in the projector and the laser printer. However, such mirror size limits the application distance. Taking the application of the optical ranging radar as an example, the application scenario ranges from as near as tens of meters to as far as hundreds of meters, which have greater intensity requirements for the laser source and the light intensity reflection, so it is difficult for the small-sized micro mirror to be applied to such scenario. However, if the size of the micro mirror is increased, it is necessary to consider whether the driving force in the piezoelectric driving measure is sufficient to drive the large-sized micro mirror to twist and rotate to achieve a mechanical rotation angle of ±15 degrees or more.

The information disclosed in this Background section is only for enhancement of understanding of the background of the described technology and therefore it may contain information that does not form the prior art that is already known to a person of ordinary skill in the art. Further, the information disclosed in the Background section does not mean that one or more problems to be resolved by one or more embodiments of the invention was acknowledged by a person of ordinary skill in the art.

### SUMMARY

The disclosure provides a micro scanning mirror, which can drive a large-sized micro mirror to rotate at an appropriate rotation angle and has good reliability.

The other objectives and advantages of the disclosure can be further understood from the technical features disclosed in the disclosure.

In order to achieve one, a part, or all of the above objectives or other objectives, an embodiment of the disclosure provides a micro scanning mirror. The micro scanning mirror includes a fixed substrate, a lens, and multiple cantilevers. The fixed substrate has an opening. The lens is located in the opening and has a central axis parallel to a surface of the fixed substrate, and the central axis passes through a center of the lens. The cantilevers are located in the opening and are disposed in line symmetry relative to the central axis, and each cantilever includes a piezoelectric material structure, multiple first drive electrodes, and multiple second drive electrodes. The piezoelectric material structure includes a connecting part, a folding part, and a fixed part. The connecting part connects the lens along a direction parallel to the central axis. The folding part has a bending region and multiple drive electrode regions. The fixed part is connected to the fixed substrate, and the folding part is connected to the connecting part and the fixed part. The first drive electrodes and the second drive electrodes are respectively located in the corresponding drive electrode regions of the folding part, the first drive electrodes and the second drive electrodes are arranged at intervals from one side of the connecting part to one side of the fixed part, wherein the drive electrode regions where the first drive electrodes located on are located on one side of the central axis, the drive electrode regions where the second drive electrodes located on are located on another side of the central axis, and the plurality of drive electrode regions where the plurality of first drive electrodes located on and the plurality of drive electrode regions where the plurality of second drive electrodes located on are disposed in line symmetry with the central axis.

Based on the above, the embodiments of the disclosure have at least one of the following advantages or effects. In the micro scanning mirror of the embodiments of the disclosure, through the configuration of the connecting part, the folding part, and the fixed part of the piezoelectric material structure of each cantilever, the configuration space of the cantilever can be saved, thereby increasing the usage area of the chip while taking into account the miniaturization and the production cost of the micro scanning mirror. Moreover, under the above configuration, the micro scanning mirror can have a lens with a diameter of 3 mm or more and a mechanical rotation angle of ±15 degrees or more. In addition, for the micro scanning mirror, the structural strength of the lens can be increased and the flatness of the lens can be strengthened through the setting of the rib reinforcement structure of the lens. In addition, for the lens of the micro scanning mirror, through the connection of the rotating shaft structure and the fixed substrate, the anti-vibration effect can be achieved when the lens rotates and the downward deviation of the lens during the rotation process can be reduced.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a front schematic view of a micro scanning mirror according to an embodiment of the disclosure.

FIG. 1B is a bottom schematic view of the micro scanning mirror of FIG. 1A.

FIG. 2A is a schematic view of waveforms of applying driving voltage to a first drive electrode and a second drive electrode of FIG. 1A.

FIG. 2B and FIG. 2C are schematic views of rotation situations of the micro scanning mirror of FIG. 2A respectively at a first timing and a second timing.

FIG. 2D is a schematic view of a relationship curve of the driving voltage of the first drive electrode or the second drive electrode of FIG. 2A and a rotation angle of the micro scanning mirror.

FIG. 2E is a schematic view of a relationship curve of the rotation angle of the micro scanning mirror of FIG. 1A and a sensing voltage of a sensing electrode.

FIG. 3 is a schematic view of waveforms of applying another driving voltage to the first drive electrode and the second drive electrode of FIG. 1A.

FIG. 4 is a front schematic view of a micro scanning mirror according to another embodiment of the disclosure.

FIG. 5 is a front schematic view of a micro scanning mirror according to yet another embodiment of the disclosure.

FIG. 6 is a front schematic view of a micro scanning mirror according to yet another embodiment of the disclosure.

FIG. 7 is a front schematic view of a micro scanning mirror according to yet another embodiment of the disclosure.

### DETAILED DESCRIPTION OF DISCLOSED EMBODIMENTS

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the present invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled, ” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

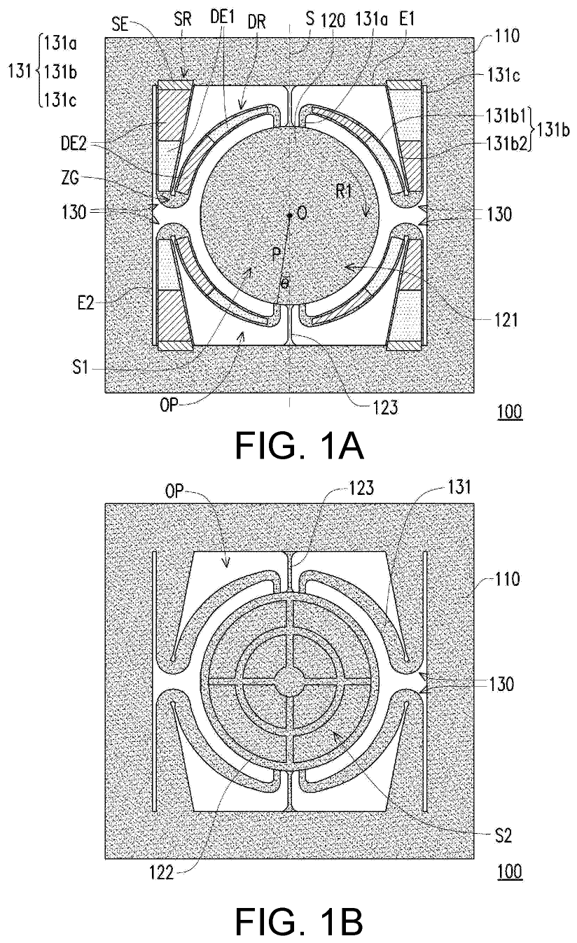

FIG. 1A is a front schematic view of a micro scanning mirror according to an embodiment of the disclosure. FIG. 1B is a back schematic view of the micro scanning mirror of FIG. 1A. Please refer to FIG. 1A and FIG. 1B. A micro scanning mirror 100 of the embodiment includes a fixed substrate 110, a lens 120, and multiple cantilevers 130. The fixed substrate 110 has an opening OP. For example, in the embodiment, the material of the fixed substrate 110 is, for example, silicon, but the disclosure is not limited thereto.

As shown in FIG. 1A and FIG. 1B, in the embodiment, the lens 120 is located in the opening OP, has a central axis S parallel to a surface of the fixed substrate 110, and has a first surface S1 and a second surface S2. The central axis S passes through a center O of the lens 120, the first surface S1 and the second surface S2 are away from each other, the first surface S1 of the lens 120 is provided with a reflective layer 121, and the second surface S2 of the lens 120 is provided with a rib reinforcement structure 122, wherein the rib reinforcement structure 122 is ring-shaped. In this way, through the configuration of the rib reinforcement structure 122, the structural strength of the lens 120 can be increased and the flatness of the lens 120 can be strengthened.

On the other hand, as shown in FIG. 1A, in the embodiment, the cantilevers 130 are located in the opening OP and are disposed in line symmetry relative to the central axis S, and each cantilever 130 includes a piezoelectric material structure 131, multiple first drive electrodes DE1, and multiple second drive electrodes DE2. Furthermore, as shown in FIG. 1A, in the embodiment, the piezoelectric material structure 131 includes a connecting part 131a, a folding part 131b, and a fixed part 131c. The connecting part 131a connects the lens 120 along a direction parallel to the central axis S. The folding part 131b has a bending region ZG and multiple drive electrode regions DR. The fixed part 131c is connected to the fixed substrate 110, and the folding part 131b is connected to the connecting part 131a and the fixed part 131c. For example, as shown in FIG. 1A, in the embodiment, a junction between the connecting part 131a of each cantilever 130 and the lens 120 forms a center connecting line P with a center of the lens 120, and an angle of an included angle θ formed by the center connecting line P and the central axis S is less than 5 degrees. It can be seen from the above that the connecting part 131a of each cantilever 130 is disposed adjacent to the central axis S.

On the other hand, specifically, as shown in FIG. 1A, in the embodiment, the width of the folding part 131b gradually decreases from one side of the fixed part 131c to one side of the connecting part 131a. More specifically, the folding part 131b has a first portion 131b1 and a second portion 131b2, the bending region ZG of the folding part 131b connects the first portion 131b1 and the second portion 131b2, the first portion 131b1 of the folding part 131b connects the connecting part 131a, and the second portion 131b2 connects the fixed part 131c. For example, as shown in FIG. 1A, in the embodiment, the first portion 131b1 of the folding part 131b is arc-shaped and extends along a circumferential direction R1 of the lens 120, the second portion 131b2 of the folding part 131b is trapezoid-shaped, the fixed part 131c is connected to an edge E1 of the opening OP of the fixed substrate 110, and the second portion 131b2 is orthogonal to the edge E1 of the opening OP and extends along another edge E2 adjacent to the edge E1 of the opening OP.

Also, as shown in FIG. 1A, in the embodiment, the first drive electrodes DE1 and the second drive electrodes DE2 are respectively located in the corresponding drive electrode regions DR of the folding part 131b, and the first drive electrodes DE1 and the second drive electrodes DE2 are arranged at intervals from one side of the connecting part 131a to one side of the fixed part 131c. For example, as shown in FIG. 1A, in the embodiment, at least one first drive electrode DE1 and at least one second drive electrode DE2 are respectively disposed on the first portion 131b1 and the second portion 131b2 of the folding part 131b. Also, as shown in FIG. 1A, the drive electrode regions DR where the first drive electrodes DE1 located on are located on one side of the central axis S, the drive electrode regions DR where the second drive electrodes DE2 located on are located on another side of the central axis S, and the drive electrode regions DR where the first drive electrodes DE1 located on and the drive electrode regions DR where the second drive electrodes DE2 located on are disposed in line symmetry with the central axis S. In addition, as shown in FIG. 1A, the first drive electrodes DE1 and the second drive electrodes DE2 are disposed in a staggered arrangement from one side of the connecting part 131a to one side of the fixed part 131c.

On the other hand, as shown in FIG. 1A, in the embodiment, the micro scanning mirror 100 further includes a rotating shaft structure 123. The rotating shaft structure 123 is located in the opening OP and connects the lens 120 and the fixed substrate 110, wherein the central axis S passes through the rotating shaft structure 123. More specifically, the rotating shaft structure 123 is located between the connecting part 131a of one of the cantilevers 130 located on one side of the central axis S and the connecting part 131a of another one of the cantilevers 130 adjacent to the one of the cantilevers 130 and located on another side of the central axis S, and the connecting part 131a of each cantilever 130 is disposed adjacent to the rotating shaft structure 123. In this way, for the lens 120, through the connection of the rotating shaft structure 123 and the fixed substrate 110, the anti-vibration effect can be achieved when the lens 120 rotates and the downward deviation of the lens 120 during the rotation process can be reduced.

In addition, as shown in FIG. 1A, in the embodiment, the fixed part 131c of the piezoelectric material structure 131 on each cantilever 130 has a sensing electrode region SR, and the micro scanning mirror 100 further includes multiple sensing electrodes SE, and the sensing electrodes SE are respectively correspondingly located in the sensing electrode region SR. In the embodiment, the sensing electrode SE may be configured to sense changes in electric charge when the fixed part 131c of the piezoelectric material structure 131 is driven by the first drive electrode DE1 or the second drive electrode DE2, thereby inferring displacement changes or angular changes when the lens 120 of the micro scanning mirror 100 rotates around the central axis S.

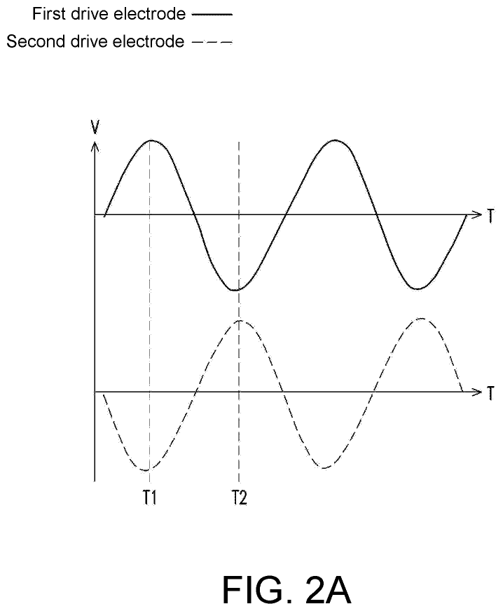

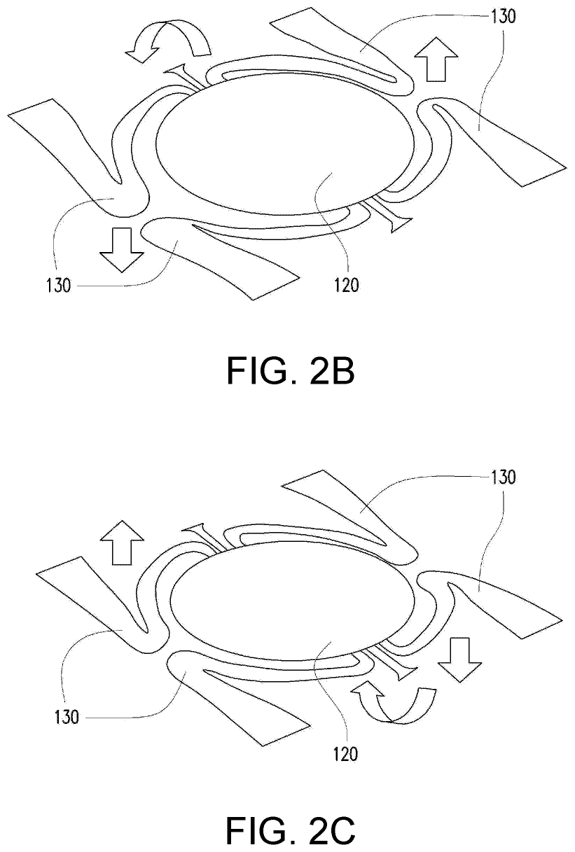

The process when the micro scanning mirror 100 rotates around the central axis S will be further explained below in conjunction with FIG. 2A to FIG. 3.

FIG. 2A is a schematic view of waveforms of applying a driving voltage to a first drive electrode and a second drive electrode of FIG. 1A. FIG. 2B and FIG. 2C are schematic views of rotation situations of the micro scanning mirror of FIG. 2A respectively at a first timing and a second timing. FIG. 2D is a schematic view of a relationship curve of the driving voltage of the first drive electrode or the second drive electrode of FIG. 2A and a rotation angle of the micro scanning mirror. FIG. 2E is a schematic view of a relationship curve of the rotation angle of the micro scanning mirror of FIG. 1A and a sensing voltage of a sensing electrode. Specifically, in the embodiment, the driving voltage applied to the first drive electrode DE1 on each cantilever 130 is the same, and the driving voltage applied to the second drive electrode DE2 on each cantilever 130 is the same. Also, as shown in FIG. 2A, in the embodiment, the magnitudes and the waveforms of the driving voltage applied to the first drive electrode DE1 and the driving voltage applied to the second drive electrode DE2 on each cantilever 130 are the same, and there is a phase difference of 180 degrees. It is worth noting that in the embodiment, although the waveforms of the driving voltage shown in FIG. 2A are exemplified as sine waves, the disclosure is not limited thereto. In other embodiments, the waveform of the driving voltage may also be a square wave, a triangle wave, or any periodic waveform.

Furthermore, as shown in FIG. 2A and FIG. 2B, in a first timing T1, a voltage source signal is provided to apply the driving voltage to the first drive electrode DE1 and the second drive electrode DE2 on each cantilever 130. Also, as shown in FIG. 1A, the drive electrode regions DR where the first drive electrodes DE1 located on are located on one side of the central axis S, the drive electrode regions DR where the second drive electrodes DE2 located on are located on another side of the central axis S, and the drive electrode regions DR where the first drive electrodes DE1 located on and the drive electrode regions DR where the second drive electrodes DE2 located on are disposed in line symmetry with the central axis S. In this way, when the piezoelectric material structure 131 is respectively driven by the first drive electrode DE1 and the second drive electrode DE2, the piezoelectric material located on two sides of the central axis S may be deformed, and the strain force on each cantilever 130 may form a first torque to drive the lens 120 to rotate with the central axis S as the rotation axis. As shown in FIG. 2B, the micro scanning mirror 100 rotates in the counterclockwise direction along the central axis S, so that the mirror may have a mechanical inclination angle to reflect a light beam projected onto the lens 120 to a specific angle.

On the other hand, as shown in FIG. 2A and FIG. 2C, the driving voltage applied to the first drive electrode DE1 and the second drive electrode DE2 on each cantilever 130 in a second timing T2 and the driving voltage applied to the first drive electrode DE1 and the second drive electrode DE2 on each cantilever 130 in the first timing T1 have the same magnitudes and waveforms, and there is a phase difference of 180 degrees. In this way, in the second timing T2, the strain force on each cantilever 130 may form a second torque that is opposite to the direction of the first torque in the first timing T1, so that the micro scanning mirror 100 may rotate in the clockwise direction along the central axis S. In this way, through applying the driving voltage with a periodic waveform, the micro scanning mirror 100 may repeat the reciprocating motion accordingly to achieve the objective of setting the mechanical rotation angle.

Furthermore, as shown in FIG. 2D, in the embodiment, there is a positive correlation between the magnitude of the driving voltage applied to the first drive electrode DE1 and the second drive electrode DE2 on each cantilever 130 and the mechanical rotation angle of the micro scanning mirror 100. Therefore, the mechanical rotation angle may be changed through adjusting the value of the driving voltage applied to the first drive electrode DE1 and the second drive electrode DE2 on each cantilever 130 according to requirements.

Also, as shown in FIG. 2E, in the embodiment, when each cantilever 130 is deformed through the strain force, the boundary stress changes, the strain force generates different degrees of charge with the difference in the torsion angle at the sensing electrode region SR of the fixed part 131c of each cantilever 130, the sensing electrode SE disposed in the sensing electrode region SR synchronously receive a sensing signal, and the waveform phase of the sensing signal is similar to the state of the driving voltage. In this way, as shown in FIG. 2E, whether the current mechanical rotation angle has reached the requirements may be judged through the waveform of the sensing signal. Moreover, if the division is performed based on the central axis S of the micro mirror, when the sensing electrode SE on the left side receives the charge generated by the compressive stress, the sensing electrode SE on the right side will receive the charge of the tensile stress, and signals of the sensing electrodes SE on the two sides may be added to improve the sensitivity of the sensing signal.

In this way, through the configuration of the connecting part 131a, the folding part 131b, and the fixed part 131c of the piezoelectric material structure 131 of each cantilever 130, the configuration space of the cantilever 130 can be saved, thereby increasing the usage area of the chip while taking into account the miniaturization and the production cost of the micro scanning mirror 100. Moreover, under the above configuration, the micro scanning mirror 100 can have the lens 120 with a diameter of 3 mm or more and the mechanical rotation angle of ±15 degrees or more.

FIG. 3 is a schematic view of waveforms of applying another driving voltage to the first drive electrode and the second drive electrode of FIG. 1A. It is worth noting that in the above embodiment, the first drive electrode DE1 and the second drive electrode DE2 on each cantilever 130 are simultaneously and continuously applied with the driving voltage with the same magnitude and waveform and with a phase difference of 180 degrees, but the disclosure is not limited thereto. As shown in FIG. 3, in another embodiment, the driving voltage may be applied to the first drive electrode DE1 and the second drive electrode DE2 on each cantilever 130 respectively in different timings, as long as the magnitudes and the waveforms of the driving voltage applied to the first drive electrode DE1 and the second drive electrode DE2 on each cantilever 130 are the same, and the first drive electrode DE1 and the second drive electrode DE2 are time-sharing driven. In this way, the micro scanning mirror 100 can also achieve the above effects and advantages, which will not be repeated here.

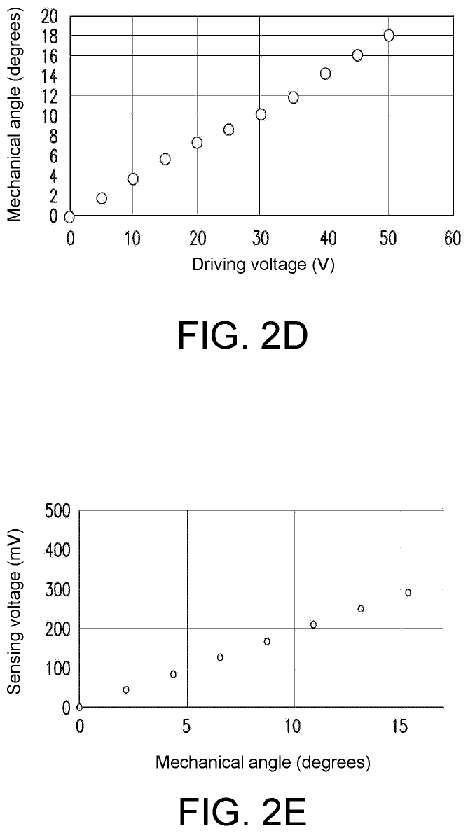

FIG. 4 is a front schematic view of a micro scanning mirror according to another embodiment of the disclosure. Please refer to FIG. 4. A micro scanning mirror 400 of FIG. 4 is similar to the micro scanning mirror 100 of FIG. 1A, but the differences are as follows. As shown in FIG. 4, in the embodiment, a first portion 431b1 of a folding part 431b and a second portion 431b2 of the folding part 431b are arc-shaped and extend along the circumferential direction R1 of the lens 120, and the second portion 431b2 of the folding part 431b is farther away from the lens 120 than the first portion 431b1 of the folding part 431b. Also, as shown in FIG. 4, in the embodiment, the widths of the first portion 431b1 of the folding part 431b and the second portion 431b2 of the folding part 431b are the same. In other words, the width of the folding part 431b remains unchanged from one side of a fixed part 431c to one side of a connecting part 431a. As shown in FIG. 4, the fixed part 431c on each cantilever 430 located on the two sides of the central axis S is disposed adjacent to the rotating shaft structure 123 and the connecting part 431a.

In this way, for the micro scanning mirror 400, through the configuration of the connecting part 431a, the folding part 431b, and the fixed part 431c of the piezoelectric material structure 431 of each cantilever 430, the configuration space of the cantilever 430 can be saved, thereby increasing the usage area of the chip while taking into consideration the miniaturization and the production cost of the micro scanning mirror 400. Moreover, under the above configuration, the micro scanning mirror 400 can have the lens 120 with a diameter of 3 mm or more and the mechanical rotation angle of ±15 degrees or more, so that the micro scanning mirror 400 can also achieve the effects and advantages similar to the micro scanning mirror 100, which will not be repeated here.

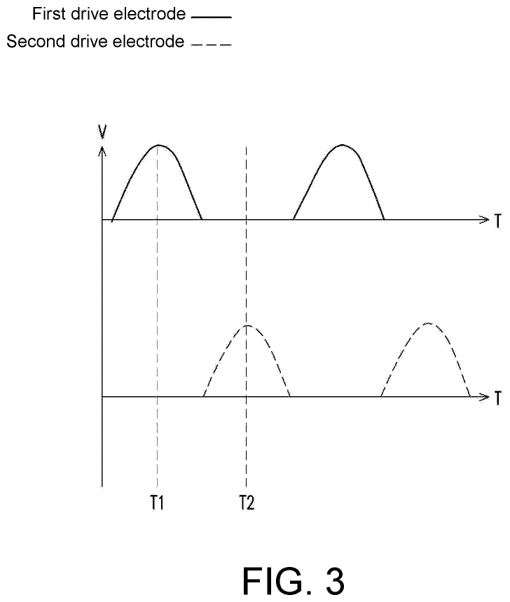

FIG. 5 is a front schematic view of a micro scanning mirror according to yet another embodiment of the disclosure. Please refer to FIG. 5. A micro scanning mirror 500 of FIG. 5 is similar to the micro scanning mirror 100 of FIG. 1A, but the differences are as follows. As shown in FIG. 5, compared with the micro scanning mirror 100 of FIG. 1A, the micro scanning mirror 500 omits the rotating shaft structure 123. In the embodiment, the width of a first portion 531b1 of a folding part 531b gradually decreases from one end that is adjacently connected to a fixed part 531c to one end that is adjacently connected to a connecting part 531a. The width of a second portion 531b2 of the folding part 531b gradually decreases from one end that is adjacently connected to the fixed part 531c to one end that is adjacently connected to the connecting part 531a. Alternatively, the first portion 531b1 and the second portion 531b2 may have equal widths. As shown in FIG. 5, the fixed part 531c on each cantilever 530 located on the two sides of the central axis S is disposed adjacent to the central axis S and the connecting part 531a. Therefore, the fixed part 531c may be used to replace the rotating shaft structure 123 and is used to achieve the anti-vibration effect when the lens 120 rotates and reduce the downward deviation of the lens 120 during the rotation process.

In this way, for the micro scanning mirror 500, through the configuration of the connecting part 531a, the folding part 531b, and the fixed part 531c of the piezoelectric material structure 531 of each cantilever 530, the configuration space of the cantilever 530 can be saved, thereby increasing the usage area of the chip while taking into account the miniaturization and the production cost of the micro scanning mirror 500. Moreover, under the above configuration, the micro scanning mirror 500 can have the lens 120 with a diameter of 3 mm or more and the mechanical rotation angle of ±15 degrees or more, so that the micro scanning mirror 500 can also achieve the effects and advantages similar to the micro scanning mirror 100, which will not be repeated here.

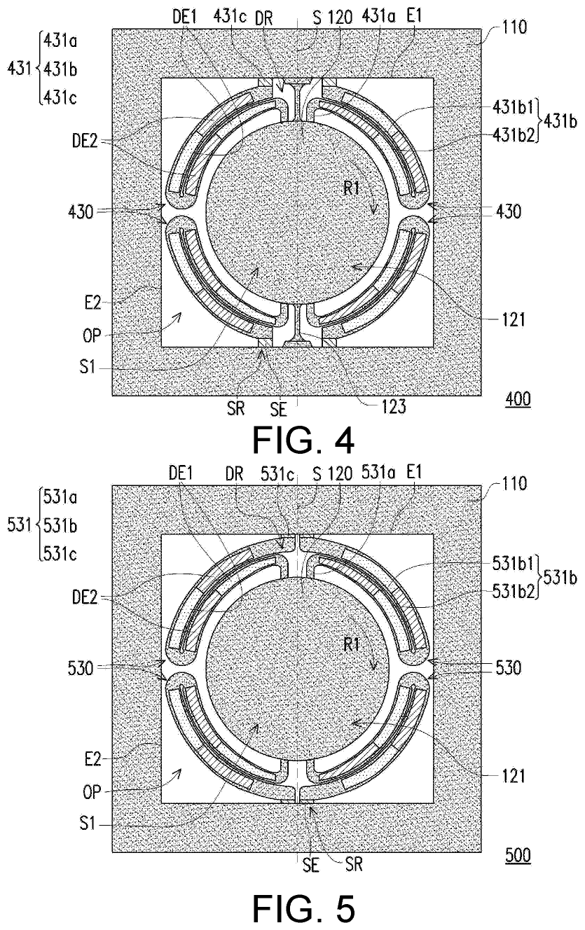

FIG. 6 is a front schematic view of a micro scanning mirror according to yet another embodiment of the disclosure. Please refer to FIG. 6. A micro scanning mirror 600 of FIG. 6 is similar to the micro scanning mirror 500 of FIG. 5, and the differences are as follows. As shown in FIG. 6, in the embodiment, a first portion 631b1 of a folding part 631b is trapezoid-shaped, a second portion 631b2 of the folding part 631b is trapezoid-shaped or quadrilateral-shaped, a fixed part 631c is connected to the edge E1 of the opening OP of a fixed substrate 160, and the first portion 631b1 and the second portion 631b2 extend along the edge E1 of the opening OP. The width of the first portion 631b1 of the folding part 631b gradually decreases from one end that is adjacently connected to the fixed part 631c to one end that is adjacently connected to a connecting part 631a. The width of the second portion 631b2 of the folding part 631b gradually decreases from one end that is adjacently connected to the fixed part 631c to one end that is adjacently connected to the connecting part 631a. Alternatively, the first portion 631b1 and the second portion 631b2 may have equal widths.

In this way, for the micro scanning mirror 600, through the configuration of the connecting part 631a, the folding part 631b, and the fixed part 631c of the piezoelectric material structure 631 of each cantilever 630, the configuration space of the cantilever 630 can be saved, thereby increasing the usage area of the chip while taking into account the miniaturization and the production cost of the micro scanning mirror 600. Moreover, under the above configuration, the micro scanning mirror 600 can have the lens 120 with a diameter of 3 mm or more and the mechanical rotation angle of ±15 degrees or more, so that the micro scanning mirror 600 can also achieve the effects and advantages similar to the micro scanning mirror 500, which will not be repeated here.

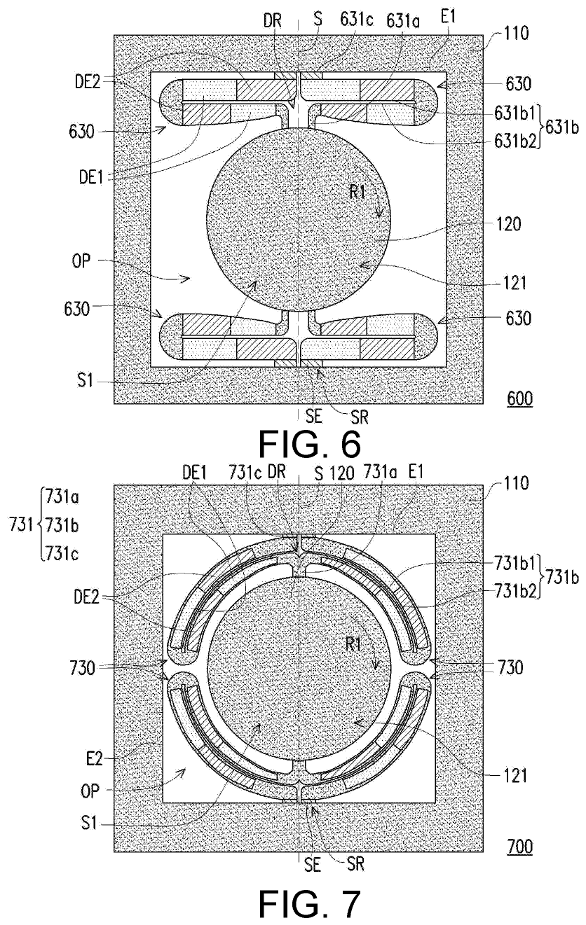

FIG. 7 is a front schematic view of a micro scanning mirror according to yet another embodiment of the disclosure. Please refer to FIG. 7. A micro scanning mirror 700 of FIG. 7 is similar to the micro scanning mirror 500 of FIG. 5, but the differences are as follows. As shown in FIG. 7, in the embodiment, a connecting part 731a of one of the cantilevers 730 located on one side of the central axis S and the connecting part 731a of another one of the cantilevers 730 adjacent to the one of the cantilevers 730 and located on another side of the central axis S are connected to the lens 120 in a mutually connected manner.

In this way, for the micro scanning mirror 700, through the configuration of the connecting part 731a, a first portion 731b1 and a second portion 731b2 of a folding part 731b, and a fixed part 731c of the piezoelectric material structure 731 of each cantilever 730, the configuration space of the cantilever 730 can be saved, thereby increasing the usage area of the chip while taking into account the miniaturization and the production cost of the micro scanning mirror 700. Moreover, under the above configuration, the micro scanning mirror 700 can have the lens 120 with a diameter of 3 mm or more and the mechanical rotation angle of ±15 degrees or more, so that the micro scanning mirror 700 can also achieve the effects and advantages similar to the micro scanning mirror 500, which will not be repeated here.

In summary, the embodiments of the disclosure have at least one of the following advantages or effects. In the micro scanning mirror of the embodiments of the disclosure, through the configuration of the connecting part, the folding part, and the fixed part of the piezoelectric material structure of each cantilever, the configuration space of the cantilever can be saved, thereby increasing the usage area of the chip while taking into account the miniaturization and the production cost of the micro scanning mirror. Moreover, under the above configuration, the micro scanning mirror can have a lens with a diameter of 3 mm or more and a mechanical rotation angle of ±15 degrees or more. In addition, for the micro scanning mirror, the structural strength of the lens can be increased and the flatness of the lens can be strengthened through the setting of the rib reinforcement structure of the lens. In addition, for the lens of the micro scanning mirror, through the connection of the rotating shaft structure and the fixed substrate, the anti-vibration effect can be achieved when the lens rotates and the downward deviation of the lens during the rotation process can be reduced.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A micro scanning mirror, comprising a fixed substrate, a lens, and a plurality of cantilevers, wherein
the fixed substrate has an opening;
the lens is located in the opening and has a central axis parallel to a surface of the fixed substrate, and the central axis passes through a center of the lens;
the plurality of cantilevers are located in the opening and are disposed in line symmetry relative to the central axis, and each of the plurality of cantilevers comprises a piezoelectric material structure, a plurality of first drive electrodes, and a plurality of second drive electrodes,
the piezoelectric material structure comprises a connecting part, a folding part, and a fixed part,
the connecting part connects the lens along a direction parallel to the central axis;
the folding part has a bending region and a plurality of drive electrode regions;
the fixed part is connected to the fixed substrate, and the folding part is connected to the connecting part and the fixed part;
the plurality of first drive electrodes and the plurality of second drive electrodes are respectively located in the corresponding plurality of drive electrode regions of the folding part, the plurality of first drive electrodes and the plurality of second drive electrodes are arranged at intervals from one side of the connecting part to one side of the fixed part, wherein the plurality of drive electrode regions where the plurality of first drive electrodes located on are located on one side of the central axis, the plurality of drive electrode regions where the plurality of second drive electrodes located on are located on another side of the central axis, and the plurality of drive electrode regions where the plurality of first drive electrodes located on and the plurality of drive electrode regions where the plurality of second drive electrodes located on are disposed in line symmetry with the central axis.

2. The micro scanning mirror according to claim 1, further comprising:
a rotating shaft structure, located in the opening and connecting the lens and the fixed substrate, wherein the central axis passes through the rotating shaft structure.

3. The micro scanning mirror according to claim 2, wherein the rotating shaft structure is further located between the connecting part of one of the plurality of cantilevers located on one side of the central axis and the connecting part of another one of the plurality of cantilevers adjacent to the one of the plurality of cantilevers located on another side of the central axis.

4. The micro scanning mirror according to claim 1, wherein a junction between the connecting part of each of the plurality of cantilevers and the lens forms a center connecting line with the center of the lens, and an angle of an included angle formed by the center connecting line and the central axis is less than 5 degrees.

5. The micro scanning mirror according to claim 1, wherein a driving voltage applied to the plurality of first drive electrodes is the same, and a driving voltage applied to the plurality of second drive electrodes is the same.

6. The micro scanning mirror according to claim 1, wherein magnitudes and waveforms of a driving voltage applied to the plurality of first drive electrodes and a driving voltage applied to the plurality of second drive electrodes are the same, and there is a phase difference of 180 degrees.

7. The micro scanning mirror according to claim 1, wherein the fixed part of each of the plurality of cantilevers has a sensing electrode region, the micro scanning mirror further comprises a plurality of sensing electrodes, and each of the plurality of sensing electrodes are respectively correspondingly located in the sensing electrode region.

8. The micro scanning mirror according to claim 1, wherein the lens has a first surface and a second surface, the first surface and the second surface are away from each other, the first surface is provided with a reflective layer, and the second surface is provided with a rib reinforcement structure.

9. The micro scanning mirror according to claim 1, wherein the folding part further has a first portion and a second portion, the bending region connects the first portion and the second portion, and at least one of the plurality of first drive electrodes and at least one of the plurality of second drive electrodes are respectively disposed on the first portion and the second portion.

10. The micro scanning mirror according to claim 9, wherein the first portion is connected to the connecting part, and the second portion is connected to the fixed part.

11. The micro scanning mirror according to claim 10, wherein the first portion is arc-shaped and extends along a circumferential direction of the lens, the second portion is trapezoid-shaped, the fixed part is connected to an edge of the opening of the fixed substrate, and the second portion is orthogonal to the edge of the opening and extends along another edge adjacent to the edge of the opening.

12. The micro scanning mirror according to claim 10, wherein the first portion and the second portion are arc-shaped and extend along a circumferential direction of the lens, and the second portion is farther from the lens than the first portion.

13. The micro scanning mirror according to claim 12, wherein widths of the first portion and the second portion are the same.

14. The micro scanning mirror according to claim 12, wherein widths of the first portion and the second portion gradually decrease from one end that is adjacently connected to the fixed part to one end that is adjacently connected to the connecting part.

15. The micro scanning mirror according to claim 10, wherein the first portion and the second portion are trapezoid-shaped, the fixed part is connected to an edge of the opening of the fixed substrate, and the first portion and the second portion extend along the edge of the opening.

16. The micro scanning mirror according to claim 1, wherein a width of the folding part gradually decreases from one side of the fixed part to one side of the connecting part.

17. The micro scanning mirror according to claim 1, wherein the connecting part of one of the plurality of cantilevers located on one side of the central axis and the connecting part of another one of the plurality of cantilevers adjacent to the one of the plurality of cantilevers located on another side of the central axis are connected to the lens in a mutually connected manner.
